(19) United States
(12) Patent Application Publication
(10) Pub. No.: US 2022/0415777 A1
(43) Pub. Date: Dec. 29, 2022

(54) SEMICONDUCTOR PACKAGE

(71) Applicant: Powerchip Semiconductor Manufacturing Corporation, Hsinchu (TW)

(72) Inventors: Chun-Sheng Chen, Hsinchu City (TW); Chiu-Tsung Huang, Hsinchu City (TW)

(73) Assignee: Powerchip Semiconductor Manufacturing Corporation, Hsinchu (TW)

(21) Appl. No.: 17/402,618

(22) Filed: Aug. 16, 2021

(30) Foreign Application Priority Data
Jun. 25, 2021 (TW) 110123375

(51) Int. Cl. H01L 23/498; H01L 25/065

(52) U.S. Cl. CPC H01L 23/49833; H01L 25/0652; H01L 23/49838; H01L 2225/0652

(57) ABSTRACT

A semiconductor package including a substrate, interposers, chips, and a dummy interposer is provided. The interposers are stacked on the substrate. The chips are located on the interposers. The chip is electrically connected to the interposer. The dummy interposer is located between the interposer and the substrate and is electrically connected to the interposer. The chip is not located between the dummy interposer and the interposer.

### CROSS-REFERENCE TO RELATED APPLICATION

This application claims the priority benefit of Taiwan application serial no. 110123375, filed on Jun. 25, 2021. The entirety of the above-mentioned patent application is hereby incorporated by reference herein and made a part of this specification.

### BACKGROUND OF THE INVENTION

### Field of the Invention

The invention relates to a semiconductor structure, and particularly relates to a semiconductor package.

### Description of Related Art

During the packaging process of the integrated circuit (IC), the semiconductor chip can be stacked, and the semiconductor chip can be combined with another package component (e.g., interposer and package substrate). Therefore, the resulting package can be referred to as a three-dimensional (3D) semiconductor package. However, how to further improve the design flexibility and the packaging density of the semiconductor package is the goal of continuous efforts at present.

### SUMMARY OF THE INVENTION

The invention provides a semiconductor package, which can improve the design flexibility and the packaging density of the semiconductor package.

The invention provides a semiconductor package, which includes a substrate, interposers, chips, and a dummy interposer. The interposers are stacked on the substrate. The chips are located on the interposers. The chip is electrically connected to the interposer. The dummy interposer is located between the interposer and the substrate and is electrically connected to the interposer. The chip is not located between the dummy interposer and the interposer.

According to an embodiment of the invention, in the semiconductor package, the interposer may be electrically connected to the substrate.

According to an embodiment of the invention, in the semiconductor package, the chip may be electrically connected to the substrate.

According to an embodiment of the invention, in the semiconductor package, the dummy interposer may be electrically connected to the substrate.

According to an embodiment of the invention, in the semiconductor package, the dummy interposer may be electrically connected to the chip by the interposer.

According to an embodiment of the invention, in the semiconductor package, the dummy interposer may have a portion extending in a direction away from the substrate.

According to an embodiment of the invention, in the semiconductor package, the dummy interposer may have upper surfaces of different heights.

According to an embodiment of the invention, in the semiconductor package, the dummy interposer may have lower surfaces of different heights.

According to an embodiment of the invention, in the semiconductor package, the dummy interposer may be located between two adjacent interposers arranged in a stack.

According to an embodiment of the invention, in the semiconductor package, the dummy interposer may be located between another dummy interposer and the interposer.

According to an embodiment of the invention, in the semiconductor package, the dummy interposer may be located between another dummy interposer and the substrate.

According to an embodiment of the invention, in the semiconductor package, sizes of two adjacent interposers arranged in a stack may decrease in a direction away from the substrate.

According to an embodiment of the invention, in the semiconductor package, sizes of two adjacent interposers arranged in a stack may increase in a direction away from the substrate.

According to an embodiment of the invention, the semiconductor package may further include a dummy chip. The dummy chip is located between the interposer and the substrate and is electrically connected to the interposer.

According to an embodiment of the invention, in the semiconductor package, the chip is not located between the dummy chip and the interposer.

According to an embodiment of the invention, in the semiconductor package, the dummy chip may be located between two adjacent interposers arranged in a stack.

According to an embodiment of the invention, in the semiconductor package, the dummy chip may be located between the interposer and the dummy interposer.

According to an embodiment of the invention, in the semiconductor package, the dummy chip may be located between two adjacent dummy interposers arranged in a stack.

According to an embodiment of the invention, in the semiconductor package, the dummy chip may be electrically connected to the chip by the interposer.

According to an embodiment of the invention, in the semiconductor package, the dummy interposer may be located between the dummy chip and the interposer.

Based on the above description, in the semiconductor package according to the invention, the dummy interposer has the support function and the electrical connection function, and the configuration and the shape of the dummy interposer can be adjusted as needed. Therefore, the design of the semiconductor package can become more flexible, and the packaging density can be improved.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a semiconductor package according to an embodiment of the invention.

FIG. 2A to FIG. 2I are schematic views illustrating dummy interposers according to another embodiments of the invention.

FIG. 3 is a schematic view illustrating a semiconductor package according to another embodiment of the invention.

### DESCRIPTION OF THE EMBODIMENTS

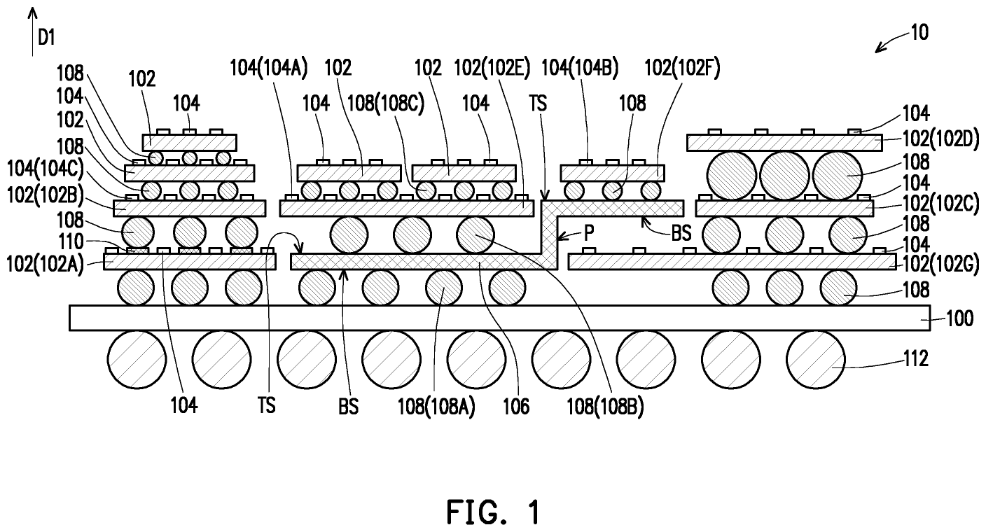

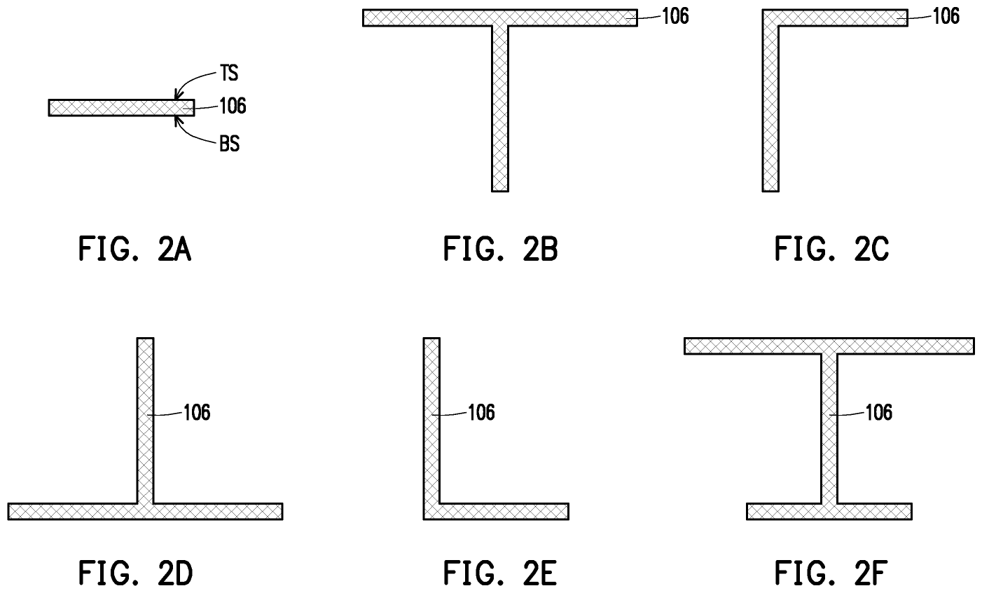

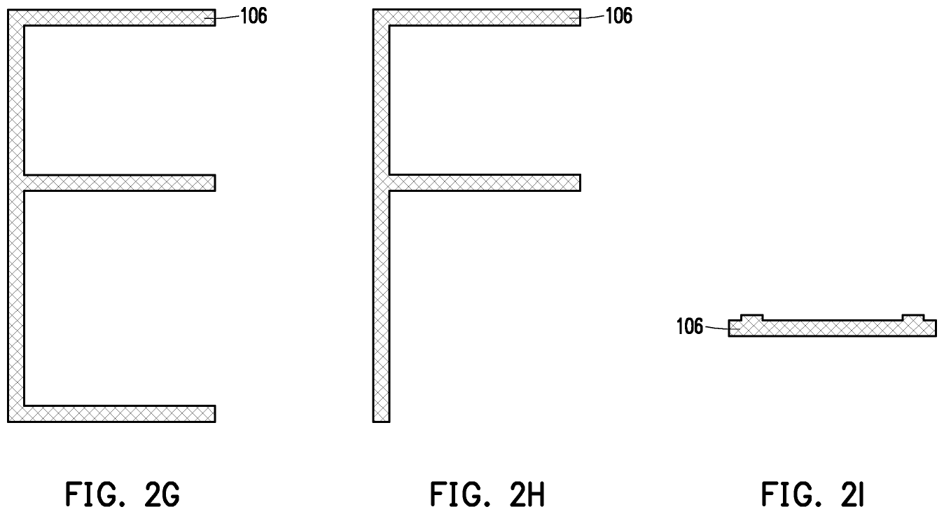

FIG. 1 is a schematic view illustrating a semiconductor package according to an embodiment of the invention. FIG. 2A to FIG. 2I are schematic views illustrating dummy interposers according to another embodiments of the invention.

Referring to FIG. 1, a semiconductor package 10 includes a substrate 100, interposers 102, chips 104, and a dummy interposer 106. The substrate 100 may be a package substrate. In some embodiments, the package substrate may include a substrate, a redistribution layer, a dielectric layer, and a via, but the invention is not limited thereto. The material of the substrate of the package substrate may be silicon (e.g., single crystal silicon or polysilicon), glass, organic material, ceramic, composite material, or a combination thereof. In addition, the semiconductor package 10 may further include connection terminals 108. The connection terminal 108 may be a bump (e.g., solder ball), but the invention is not limited thereto.

The interposers 102 are stacked on the substrate 100. In some embodiments, the interposer 102 may provide a fan-out function or a fan-in function. The interposer 102 may be used to carry the chip 104. Two adjacent interposers 102 (e.g., interposer 102A and interposer 102B) arranged in a stack may be electrically connected to each other by the connection terminal 108. In some embodiments, the interposer 102 may include a substrate, a redistribution layer, a dielectric layer, and a via, but the invention is not limited thereto. The material of the substrate of the interposer 102 may be silicon (e.g., single crystal silicon or polysilicon), glass, organic material, ceramic, composite material, or a combination thereof. In some embodiments, the interposer 102 may be an interposer having redistribution layers on two sides (i.e., interposer of double-side routing) or an interposer having a redistribution layer on one side (i.e., interposer of single-sided routing).

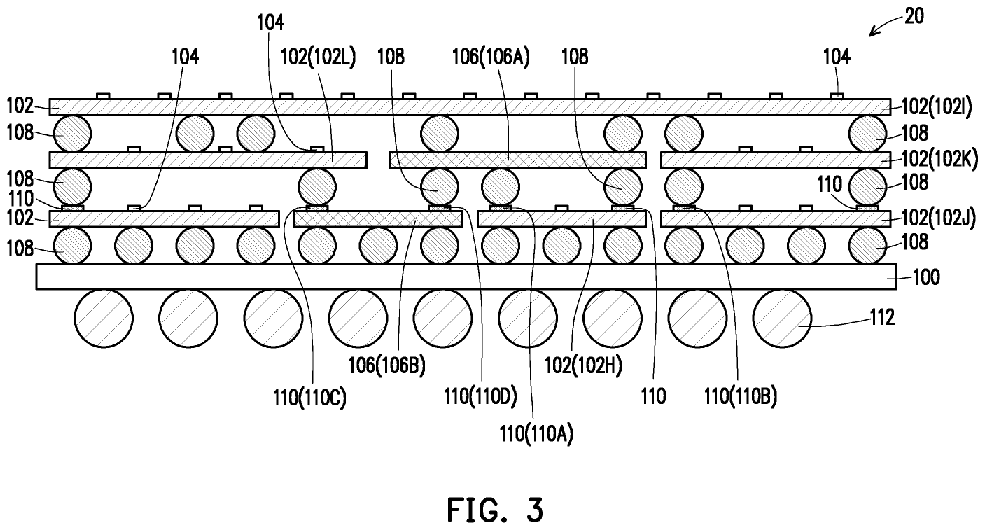

In some embodiments, as shown in FIG. 1, the sizes (e.g., top view areas or widths) of two adjacent interposers 102 arranged in a stack may decrease or increase in the direction D1 away from the substrate 100 (FIG. 1), but the invention is not limited thereto. For example, the sizes (e.g., top view areas or widths) of the interposer 102A and the interposer 102B arranged in a stack and adjacent to each other may decrease in the direction D1 away from the substrate 100. The sizes (e.g., top view areas or widths) of the interposer 102C and the interposer 102D arranged in a stack and adjacent to each other may increase in the direction D1 away from the substrate 100. In other embodiments, the sizes (e.g., top view areas or widths) of two adjacent interposers 102 arranged in a stack may be the same as each other (FIG. 3).

In some embodiments, as shown in FIG. 1, the sizes (e.g., radiuses or widths) of two adjacent connection terminals 108 arranged in a stack may decrease or increase in the direction D1 away from the substrate 100, but the invention is not limited thereto. For example, the sizes (e.g., radiuses or widths) of the connection terminal 108A and the connection terminal 108B arranged in a stack and adjacent to each other may increase in the direction D1 away from the substrate 100. The sizes (e.g., radiuses or widths) of the connection terminal 108B and the connection terminal 108C arranged in a stack and adjacent to each other may decrease in the direction D1 away from the substrate 100. In other embodiments, the sizes (e.g., radiuses or widths) of two adjacent connection terminals 108 arranged in a stack may be the same as each other (FIG. 3).

The chips 104 are located on the interposers 102. The chip 104 is electrically connected to the interposer 102. The chip 104 may be electrically connected to the corresponding interposer 102 by a connection terminal (not shown), but the invention is not limited thereto. The connection terminal may be a bump (e.g., solder ball), but the invention is not limited thereto. The chip 104 may be a functional chip such as a power chip, a radio frequency chip, a graphics chip, or a memory chip.

The dummy interposer 106 is located between the interposer 102 and the substrate 100 and is electrically connected to the interposer 102. In some embodiments, the dummy interposer 106 may provide a fan-out function or a fan-in function. The dummy interposer 106 does not directly carry the chip 104. That is, the chip 104 is not located between the dummy interposer 106 and the interposer 102. For example, the chip 104 is not located between the dummy interposer 106 and the interposer 102E. The chip 104 is not located between the dummy interposer 106 and the interposer 102F. The dummy interposer 106 can have the support function and the electrical connection function, so that the design of the semiconductor package 10 can become more flexible, and the packaging density can be improved. In addition, since the dummy interposer 106 can have the support function and the electrical connection function (for example, to transmit signal flow, data flow, or power), the dummy interposer 106 can be disposed at any position in the semiconductor package 10 where support and electrical connection are required, and the configuration of the dummy interposer 106 is not limited to FIG. 1. In the present embodiment, a portion of the dummy interposer 106 may be located between the interposer 102E and the substrate 100, a portion of the dummy interposer 106 may be located between the interposer 102F and the substrate 100, and a portion of the dummy interposer 106 may be located between the interposer 102F and the interposer 102G, but the invention is not limited thereto.

In some embodiments, the dummy interposer 106 may include a substrate, a redistribution layer, a dielectric layer, and a via, but the invention is not limited thereto. The material of the substrate of the dummy interposer 106 may be silicon (e.g., single crystal silicon or polysilicon), glass, organic material, ceramic, composite material, or a combination thereof.

In some embodiments, the dummy interposer 106 may be a dummy interposer having redistribution layers on two sides (i.e., dummy interposer of double-side routing) or a dummy interposer having a redistribution layer on one side (i.e., dummy interposer of single-sided routing).

In some embodiments, the dummy interposer 106 may be electrically connected to the chip 104 by the interposer 102. For example, the dummy interposer 106 may be electrically connected to the chip 104A located on the interposer 102E by the connection terminal 108 and the interposer 102E. The dummy interposer 106 may be electrically connected to the chip 104B located on the interposer 102F by the connection terminal 108 and the interposer 102F.

In the present embodiment, the dummy interposer 106 may have a portion P extending in the direction D1 away from the substrate 100, but the invention is not limited thereto. Furthermore, the dummy interposer 106 may have upper surfaces TS of different heights, but the invention is not limited thereto. Moreover, the dummy interposer 106 may have lower surfaces BS of different heights, but the invention is not limited thereto. On the other hand, the shape of the dummy interposer 106 is not limited to the shape in FIG. 1. The shape of the dummy interposer 106 may be adjusted according to the requirements of support and electrical connection. In other embodiments, the dummy interposer 106 may have a shape as shown in FIG. 2A to FIG. 21 according to the requirements of support and electrical connection. As shown in FIG. 2A, the dummy interposer 106 may only have one upper surface TS and one lower surface BS.

In addition, the semiconductor package 10 may further include a dummy chip 110. The dummy chip 110 can have the support function and the electrical connection function (for example, to transmit signal flow, data flow, or power), so that the design of the semiconductor package 10 can become more flexible, and the packaging density can be further improved. In the present embodiment, the dummy chip 110 may have the support function and the electrical connection function, but the dummy chip 110 does not have other functions. That is, the dummy chip 110 refers to a chip that has the support function and the electrical connection function but does not have other functions. The dummy chip 110 is located between the interposer 102 and the substrate 100 and is electrically connected to the interposer 102. In the present embodiment, the dummy chip 110 may be located on the interposer 102, but the invention is not limited thereto. The dummy chip 110 may be electrically connected to the corresponding interposer 102 by a connection terminal (not shown), but the invention is not limited thereto. The connection terminal may be a bump (e.g., solder ball), but the invention is not limited thereto. Furthermore, the dummy chip 110 does not directly carry the chip 104. That is, the chip 104 is not located between the dummy chip 110 and the interposer 102 (e.g., the interposer 102B). Moreover, since the dummy chip 110 can have the support function and the electrical connection function, the dummy chip 110 can be disposed at any position in the semiconductor package 10 where support and electrical connection are required, and the configuration of the dummy chip 110 is not limited to FIG. 1. For example, the dummy chip 110 may be located between two adjacent interposers 102 (e.g., interposer 102A and interposer 102B) arranged in a stack, but the invention is not limited thereto.

In some embodiments, the dummy chip 110 may include a substrate, a redistribution layer, a dielectric layer, and a via, but the invention is not limited thereto. The material of the substrate of the dummy chip 110 may be silicon (e.g., single crystal silicon or polysilicon), glass, organic material, ceramic, composite material, or a combination thereof. In some embodiments, the dummy chip 110 may be a dummy chip having redistribution layers on two sides (i.e., dummy chip of double-side routing) or a dummy chip having a redistribution layer on one side (i.e., dummy chip of single-sided routing).

In some embodiments, the dummy chip 110 may be electrically connected to the chip 104 by the interposer 102. For example, the dummy chip 110 may be electrically connected to the chip 104C located on the interposer 102B by the connection terminal 108 and the interposer 102B.

In some embodiments, the interposer 102 may be electrically connected to the substrate 100. For example, the interposer 102 may be electrically connected to the substrate 100 by at least one of the connection terminal 108, another interposer 102, the dummy interposer 106, and the dummy chip 110 (FIG. 1 and FIG. 3). In some embodiments, the chip 104 may be electrically connected to the substrate 100. For example, the chip 104 may be electrically connected to the substrate 100 by at least one of the interposer 102, the connection terminal 108, the dummy interposer 106, and the dummy chip 110 (FIG. 1 and FIG. 3). The dummy interposer 106 may be electrically connected to the substrate 100. In the present embodiment, as shown in FIG. 1, the dummy interposer 106 may be electrically connected to the substrate 100 by the connection terminal 108, but the invention is not limited thereto. In other embodiments, the dummy interposer 106 may be electrically connected to the substrate 100 by at least one of the interposer 102, the connection terminal 108, another dummy interposer 106, and the dummy chip 110 (FIG. 3). In the present embodiment, as shown in FIG. 1, the dummy chip 110 may be electrically connected to the substrate 100 by the interposer 102 and the connection terminal 108, but the invention is not limited thereto. In other embodiments, the dummy chip 110 may be electrically connected to the substrate 100 by at least one of the interposer 102, the connection terminal 108, the dummy interposer 106, and another dummy chip 110 (FIG. 3).

Furthermore, the semiconductor package 10 may further include connection terminals 112. The connection terminal 112 is located at the bottom of the substrate 100, so that the substrate 100 may be electrically connected to another electronic component. The connection terminal 112 may be a bump (e.g., solder ball), but the invention is not limited thereto.

In some embodiments, the semiconductor package 10 may include an encapsulant (not shown) according to the product requirement, thereby protecting other components in the semiconductor package 10. In other embodiments, the semiconductor package 10 may not include the encapsulant.

Based on the above embodiment, in semiconductor package 10, the dummy interposer 106 has the support function and the electrical connection function, and the configuration and the shape of the dummy interposer 106 can be adjusted as needed. Therefore, the design of the semiconductor package 10 can become more flexible, and the packaging density can be improved.

FIG. 3 is a schematic view illustrating a semiconductor package according to another embodiment of the invention. The same or similar components in FIG. 3 and FIG. 1 are denoted by the same symbols, and the description thereof is omitted.

Referring to FIG. 3, in the semiconductor package 20, the dummy interposer 106 is located between the interposer 102 and the substrate 100 and is electrically connected to the interposer 102. For example, in the semiconductor package 20, the dummy interposer 106A may be located between two adjacent interposer 102 (e.g., interposer 102H and interposer 102I) arranged in a stack. The dummy interposer 106A may be located between another dummy interposer 106 (e.g., dummy interposer 106B) and the interposer 102I. The dummy interposer 106B may be located between another dummy interposer 106 (e.g., dummy interposer 106A) and the substrate 100. The dummy interposer 106A may be located between the dummy chip 110A and the interposer 102I.

In the semiconductor package 20, the dummy chip 110 is located between the interposer 102 and the substrate 100 and is electrically connected to the interposer 102. The dummy chip 110 may be located on the interposer 102 or the dummy interposer 106. For example, in the semiconductor package 20, the dummy chip 110B may be located between two adjacent interposers 102 (e.g., interposer 102J and interposer 102K) arranged in a stack. The dummy chip 110C may be located between the interposer 102L and the dummy interposer 106B.

The dummy chip 110D may be located between two adjacent dummy interposers 106 (dummy interposer 106A and dummy interposer 106B) arranged in a stack. The dummy chip 110 may be electrically connected to the corresponding interposer 102 or the corresponding dummy interposer 106 by a connection terminal (not shown), but the invention is not limited thereto. The connection terminal may be a bump (e.g., solder ball), but the invention is not limited thereto.

In addition, in the semiconductor package 20, the sizes (e.g., radiuses or widths) of two adjacent connection terminals 108 arranged in a stack may be the same as each other. The sizes (e.g., top view areas or widths) of two adjacent interposers 102 (e.g., interposer 102J and interposer 102K) arranged in a stack may be the same as each other.

Moreover, the shape of the dummy interposer 106 is not limited to the shape in FIG. 3. The shape of the dummy interposer 106 may be adjusted according to the requirements of support and electrical connection. For example, the dummy interposer 106B, the dummy chip 110C, and the dummy chip 110D in FIG. 3 may be replaced with the dummy interposer 106 as shown in FIG. 21.

Based on the above embodiment, in semiconductor package 20, the dummy interposer 106 has the support function and the electrical connection function, and the configuration and the shape of the dummy interposer 106 can be adjusted as needed. Therefore, the design of the semiconductor package 20 can become more flexible, and the packaging density can be improved.

In summary, the semiconductor package of the aforementioned embodiments has the dummy interposer, and the dummy interposer has the support function and the electrical connection function, thereby improving the design flexibility and the packaging density of the semiconductor package.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor package, comprising:
a substrate;
interposers stacked on the substrate;
chips located on the interposers, wherein the chip is electrically connected to the interposer; and
a dummy interposer located between the interposer and the substrate and electrically connected to the interposer, wherein the chip is not located between the dummy interposer and the interposer.

2. The semiconductor package according to claim 1, wherein the interposer is electrically connected to the substrate.

3. The semiconductor package according to claim 1, wherein the chip is electrically connected to the substrate.

4. The semiconductor package according to claim 1, wherein the dummy interposer is electrically connected to the substrate.

5. The semiconductor package according to claim 1, wherein the dummy interposer is electrically connected to the chip by the interposer.

6. The semiconductor package according to claim 1, wherein the dummy interposer has a portion extending in a direction away from the substrate.

7. The semiconductor package according to claim 1, wherein the dummy interposer has upper surfaces of different heights.

8. The semiconductor package according to claim 1, wherein the dummy interposer has lower surfaces of different heights.

9. The semiconductor package according to claim 1, wherein the dummy interposer is located between two adjacent interposers arranged in a stack.

10. The semiconductor package according to claim 1, wherein the dummy interposer is located between another dummy interposer and the interposer.

11. The semiconductor package according to claim 1, wherein the dummy interposer is located between another dummy interposer and the substrate.

12. The semiconductor package according to claim 1, wherein sizes of two adjacent interposers arranged in a stack decrease in a direction away from the substrate.

13. The semiconductor package according to claim 1, wherein sizes of two adjacent interposers arranged in a stack increase in a direction away from the substrate.

14. The semiconductor package according to claim 1, further comprising:
a dummy chip located between the interposer and the substrate and electrically connected to the interposer.

15. The semiconductor package according to claim 14, wherein the chip is not located between the dummy chip and the interposer.

16. The semiconductor package according to claim 14, wherein the dummy chip is located between two adjacent interposers arranged in a stack.

17. The semiconductor package according to claim 14, wherein the dummy chip is located between the interposer and the dummy interposer.

18. The semiconductor package according to claim 14, wherein the dummy chip is located between two adjacent dummy interposers arranged in a stack.

19. The semiconductor package according to claim 14, wherein the dummy chip is electrically connected to the chip by the interposer.

20. The semiconductor package according to claim 14, wherein the dummy interposer is located between the dummy chip and the interposer.
